(19) United States
(12) Patent Application Publication
(10) Pub. No.: US 2025/0260212 A1
(43) Pub. Date: Aug. 14, 2025

(54) HIGH EFFICIENCY DENSE WAVELENGTH MULTIPLEXING

(71) Applicant: TRUMPF Photonics, Inc., Cranbury, NJ (US)

(72) Inventors: Stefan Heinemann, Bozeman, MT (US); Carlo Holly, Jersey City, NJ (US)

(21) Appl. No.: 18/440,993

(22) Filed: Feb. 14, 2024

(51) Int. Cl. H01S 5/40; H01S 3/10; H01S 5/14

(52) U.S. Cl. CPC H01S 5/4062; H01S 3/10061; H01S 5/141; H01S 5/4087

(57) ABSTRACT

An external cavity laser apparatus includes a plurality of beam emitters configured to emit a plurality of emitted beams, an angular dispersive optic configured to combine the plurality of emitted beams into a combined input beam, and an optical beam splitter configured to reflect a primary portion of the combined input beam as a combined output beam, and transmit a secondary portion of the combined input beam as a combined feedback input beam. The optical beam splitter has a reflectance and a transmittance that is unequal to the reflectance. The apparatus further includes a spatial filtering element configured to filter the combined feedback input beam to form a combined feedback beam. A secondary portion of the combined feedback beam is transmitted by the optical beam splitter and is directed by the angular dispersive optic to the plurality of beam emitters to stabilize the wavelengths of the plurality of emitted beams.

### FIELD

Embodiments of the present invention relate to an external cavity laser apparatus and a method of dense wave multiplexing.

### BACKGROUND

Dense wavelength multiplexing (DWM) techniques spatially superimpose a plurality of input beams to produce a single combined high power output beam. In order to ensure that the combined high power output beam is of sufficiently high quality, i.e. has a sufficiently small beam parameter product (BPP), for desired applications, DWM techniques provide for wavelength-locking of the individual emitters that emit the plurality of input beams. Wavelength-locking refers to narrowing the emission spectrum of an emitter about a particular wavelength by causing the emitter to emit a substantial majority of its radiation within a narrow wavelength spectrum. DWM techniques achieve wavelength-locking by providing, via an external resonator cavity, feedback to each individual emitter that stimulates emission of radiation at wavelengths within the narrow spectrum, thereby decreasing the relative population of radiation at undesired wavelengths.

Without wavelength-locking, individual emitters will emit larger portions of radiation at non-desired wavelengths. Radiation at non-desired wavelengths increases the BPP of combined beams produced by spectral-angular dispersive elements, e.g. diffraction gratings. Additionally, radiation having non-desired wavelengths can induce temporal fluctuation in the output power by means of spectral crosstalk between neighboring emitters. Spectral crosstalk refers to the situation where a portion of the radiation emitted by one individual emitter is directed into a different individual emitter as feedback. In order to limit the levels of radiation emitted at non-desired wavelengths and thereby increase the fidelity of the wavelength-locking process, DWM techniques can utilize wavelength filtering elements. Wavelength filtering elements are designed to remove radiation having non-desired wavelengths from the low power input beams as those beams propagate through external cavities.

Wavelength filtering elements (also referred to as spatial filtering elements) usually include optical components such as lenses and one or more apertures. These optical components can contribute to the optical loss of the external resonator. Thus, improvements are needed for achieving high efficiency dense wavelength multiplexing.

### SUMMARY

In a first aspect of the present invention, an external cavity laser apparatus is provided. The external cavity laser apparatus includes a plurality of beam emitters configured to emit a plurality of emitted beams, each emitted beam having a respective wavelength, an angular dispersive optic disposed in an optical path of the plurality of emitted beams and configured to combine the plurality of emitted beams into a combined input beam, and an optical beam splitter disposed in an optical path of the combined input beam and having a first reflectance for a first polarization state and a first transmittance for the first polarization state, the first transmittance being unequal to the first reflectance. The optical beam splitter is configured to reflect a primary portion of the combined input beam as a combined output beam, and transmit a secondary portion of the combined input beam as a combined feedback input beam. The external cavity laser apparatus further includes a spatial filtering clement disposed in an optical path of the combined feedback input beam, and a first high reflectance (HR) mirror disposed in the optical path of the combined feedback input beam downstream from the spatial filtering element. The first HR mirror is configured to reflect the combined feedback input beam transmitted through the spatial filtering element once back through the spatial filtering element again to form a combined feedback beam. A primary portion of the combined feedback beam is reflected by the optical beam splitter, and a secondary portion of the combined feedback beam is transmitted by the optical beam splitter toward the angular dispersive optic. The secondary portion of the combined feedback beam is directed by the angular dispersive optic back to the plurality of beam emitters to stabilize the wavelengths of the plurality of emitted beams.

According to some embodiments, the external cavity laser apparatus further includes a second HR mirror disposed in an optical path of the primary portion of the combined feedback beam reflected by the optical beam splitter. The second HR mirror is configured to reflect the primary portion of the combined feedback beam back toward the optical beam splitter. According to some embodiments, the second HR mirror has a reflectance that is greater than 98%.

According to some embodiments, the first reflectance for the first polarization state is greater than the first transmittance for the first polarization state. In some embodiments, the first reflectance for the first polarization state is greater than 80%, and the first transmittance for the first polarization state is less than 20%. In some embodiments, the first reflectance for the first polarization state is greater than 90%, and the first transmittance for the first polarization state is less than 10%. In some embodiments, the optical beam splitter has a second reflectance for a second polarization state orthogonal to the first polarization state, the second reflectance being greater than 98%.

In some embodiments, the first HR mirror has a reflectance that is greater than 98%.

In some embodiments, the angular dispersive optic is a polarization insensitive grating.

In some embodiments, the external cavity laser apparatus further includes a first position-to-angle transform optic disposed in the optical path of the plurality of emitted beams upstream from the angular dispersive optic. The first position-to-angle transform optic is configured to impart upon each of the plurality of emitted beams an angle of incidence with respect to the angular dispersive optic.

In some embodiments, the angular dispersive optic has a wavelength-dependent angular dispersion function, so that the angular dispersive optic combines the plurality of emitted beams into the combined input beam by imparting a wavelength-dependent angular spectrum determined by the wavelength-dependent angular dispersion function on the plurality of emitted beams.

In some embodiments, the spatial filtering element includes a second position-to-angle transform optic, a third position-to-angle transform optic, and an aperture disposed between the second position-to-angle transform optic and the third position-to-angle transform optic.

In some embodiments, the external cavity laser apparatus further includes a polarizer and a polarization rotating element disposed between the optical beam splitter and the spatial filtering element in the optical path of the combined feedback input beam.

In a second aspect of the present invention, a method of dense wave multiplexing is provided. The method includes generating, using a plurality of beam emitters, a plurality of emitted beams, each emitted beam having a respective wavelength, combining, using an angular dispersive optic disposed in an optical path of the plurality of emitted beams, the plurality of emitted beams into a combined input beam, and splitting, using an optical beam splitter, the combined input beam into a primary portion and a secondary portion. An optical power of the primary portion is different than an optical power of the secondary portion. The primary portion is reflected by the optical beam splitter as a combined output beam, and the secondary portion is transmitted by the optical beam splitter as a combined feedback input beam. The method further includes passing the combined feedback input beam through a spatial filtering element to form a combined feedback beam directed toward the optical beam splitter, transmitting, using the optical beam splitter, a secondary portion of the combined feedback beam toward the angular dispersive optic, and directing, using the angular dispersive optic, the secondary portion of the combined feedback beam back to the plurality of beam emitters to stabilize the wavelengths of the plurality of emitted beams.

In some embodiments, the optical power of the primary portion of the combined input beam is greater than the optical power of the secondary portion of the combined input beam. In some embodiments, the optical power of the primary portion of the combined input beam is greater than 80% of an optical power of the combined input beam, and the optical power of the secondary portion of the combined input beam is less than 20% of the optical power of the combined input beam. In some embodiments, the optical power of the primary portion of the combined input beam is greater than 90% of the optical power of the combined input beam, and the optical power of the secondary portion of the combined input beam is less than 10% of the optical power of the combined input beam.

In some embodiments, the method further includes reflecting, using the optical beam splitter, a primary portion of the combined feedback beam, and reflecting, using a high reflectance (HR) mirror, the primary portion of the combined feedback beam back toward the optical beam splitter. In some embodiments, the HR mirror has a reflectance that is greater than 98%.

In some embodiments, the spatial filtering element includes a first position-to-angle transform optic, a second position-to-angle transform optic, and an aperture disposed between the second position-to-angle transform optic and the third position-to-angle transform optic.

In some embodiments, passing the combined feedback input beam through the spatial filtering element includes passing the combined feedback input beam through the spatial filtering element for a first time and a second time. The method further includes after passing the combined feedback input beam through the spatial filtering element for the first time, reflecting, using a high reflectance (HR) mirror, the combined feedback input beam back through the spatial filtering element for the second time.

### BRIEF DESCRIPTION OF THE DRAWINGS

Embodiments of the present invention will be described in even greater detail below based on the exemplary figures. The present invention is not limited to the exemplary embodiments. All features described and/or illustrated herein can be used alone or combined in different combinations in embodiments of the present invention. The features and advantages of various embodiments of the present invention will become apparent by reading the following detailed description with reference to the attached drawings which illustrate the following:

FIG. 1 illustrates a laser apparatus, according to an embodiment of the invention, for producing, via dense wavelength multiplexing (DWM) techniques, a single, multi-wavelength output laser beam comprising a plurality of spatially and directionally overlapped beams that each has a narrow wavelength spectrum;

FIG. 2 is a simplified diagram of the laser apparatus shown in FIG. 1, to illustrate the optical power calculations according to some embodiments; and

FIG. 3 shows a bar plot of the calculated optical powers according to some embodiments.

### DETAILED DESCRIPTION

Embodiments of the present invention provide an external cavity laser apparatus and methods for achieving high efficiency dense wavelength beam multiplexing (DWM). The external cavity laser apparatus is configured to combine a plurality of individual input beams into a single combined output beam. Certain applications, for example material processing applications such as laser cutting of sheet metal having a thickness of approximately 10 mm, require high beam quality (e.g., a BPP value less than 5 mm·mrad) and high laser power (e.g., in the kW range). DWM techniques and apparatuses often provide for precise spatial and directional overlapping of low power input beams via an external resonator cavity configured to provide feedback to the individual emitters that emit the low power input beams. The low power input beams can be provided by diode lasers, which have the advantages of possessing low costs and high efficiencies. Embodiments of the present invention can reduce the optical losses of the external resonator cavity, leading to improvements of the electro-optical efficiency of the external cavity laser apparatus.

According to embodiments of the present invention, the external cavity laser apparatus utilizes an optical beam splitter, a high reflectance mirror and a feedback system. The outcoupling reflectivity is determined by the beam splitter ratio (i.e., the ratio of the optical powers in the two branches). According to some embodiments, the beam splitter ratio is about 92% to 8%, which can result in a feedback of about 3%. By arranging the spatial filtering element in the low-power branch of the optical beam splitter instead of in the high-power branch, the optical loss of the external cavity laser apparatus can be reduced by about 5%. The output efficiency can be as high as 89%, as compared to 81% in conventional systems, thus increasing the output efficiency by approximately 8%.

By having the spatial filtering element in the low-power branch of the optical beam splitter, the high-power beam is directed to the output. Only the low-power beam experiences the optical losses of the spatial filtering element and provides the feedback of the external cavity. Additionally, a second high reflection (HR) mirror (e.g., with nearly 100% reflectivity) is arranged in the low-power branch to recoup the power reflected back from a first HR mirror and the optical beam splitter.

According to some embodiments, the external cavity laser apparatus is polarization insensitive, and can be designed for either TM or TE mode (relative to the laser diodes) for high power output radiation. Thus polarization multiplexing in a large laser system is also possible.

According to some embodiments, the optical beam splitter can be designed such that it reflects nearly all TM mode to the output, therefore reducing the required feedback compared to conventional systems. In this case, the optical beam splitter is a polarization dependent beam splitter with close to 100% reflectivity for the TM mode. Back reflected TM radiation does not contribute to the feedback inside the diode laser.

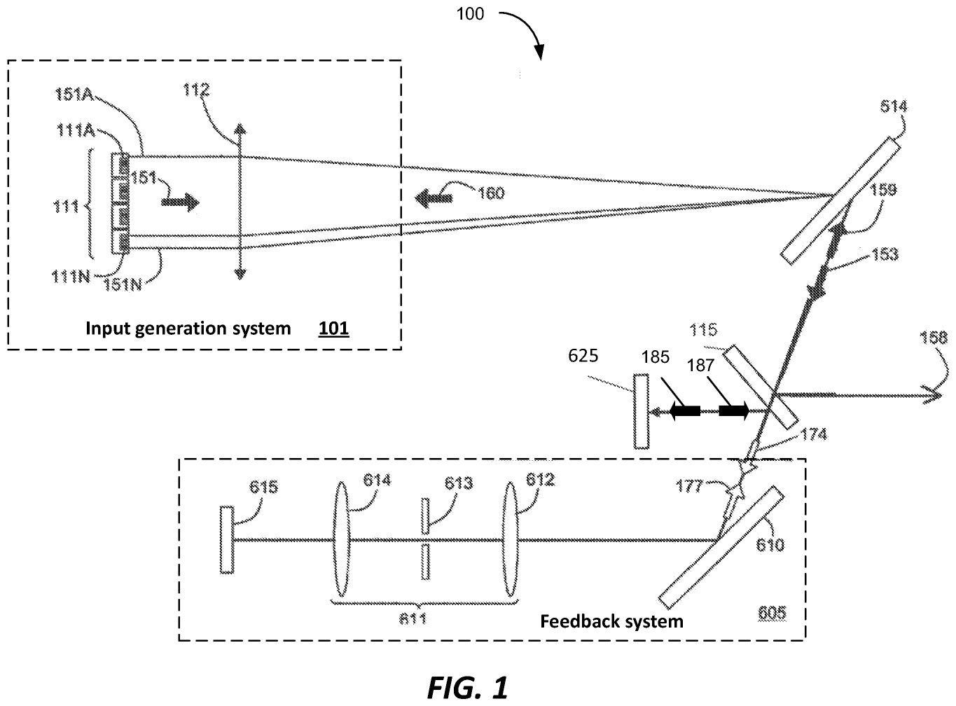

FIG. 1 illustrates an external cavity laser apparatus 100, according to an embodiment of the invention, for producing, via dense wavelength multiplexing (DWM) techniques, a single, multi-wavelength, combined output laser beam that includes a plurality of spatially and directionally overlapped individual laser beams. The external cavity laser apparatus 100 includes an input generation system 101, an angular dispersive optic 514, an optical beam splitter 115, and a feedback system 605.

The input generation system 101 includes a laser source 111 configured to produce a plurality of individual laser beams used in forming the combined output laser beam. The laser source 111 includes a plurality of individual beam emitters (e.g. 111A through 111N) that each emit a single laser beam. The individual beams emitted by the plurality of individual beam emitters are referred herein as the emitted beams 151. The emitted beams 151 include, e.g., emitted beam 151A and emitted beam 151N.

The individual beam emitters of the laser source 111 may be diode lasers, fiber lasers, solid-state lasers, or any other type of lasers. The plurality of individual beam emitters may be arranged in a one dimensional array, a two dimensional array, or a variety of other configurations. For example, the laser source 111 may be an array of diode lasers formed from vertical, horizontal, or two-dimensional stacks of diode bars, each diode bar having a plurality of individual diode laser emitters.

The individual laser emitters, e.g., diode laser emitters, are often marketed as transverse electric (TE) or transverse magnetic (TM) in reference to the polarization state of the beams they emit. However, it is possible that, due to the manufacturing and packaging process, diode lasers designed for TM emit beams that include a small TE component and vice verse.

Each of the plurality of beam emitters of the laser source 111 emits a constituent of the emitted beams 151 that includes a preferred resonant mode component and an alternative resonant mode component. The preferred resonant mode component includes photons having a wavelength that falls within a narrow spectral band that corresponds to a preferred resonant mode of the beam emitter of the laser source 111 that emitted the constituent beam. The alternative resonant mode component includes photons having a wavelength that falls outside of the narrow spectral band that corresponds to the preferred resonant mode of the beam emitter of the laser source 111 that emitted the constituent beam. Alternative resonant mode components of constituents of the emitted beams 151 that propagate through the external resonator will not be spatially and directionally overlapped upon emerging from the optical beam splitter 115, but will instead possess a residual angular spectrum. Therefore, alternative resonant mode components of constituents of the emitted beams 151 can increase the BPP of the combined output beam 158. To increase the quality of the beam output by the external cavity laser apparatus 100, it is possible to mitigate the impact of such alternative resonant mode components by incorporating a spatial filtering element 611 in the feedback system 605, as discussed in more detail below.

The input generation system 101 further includes a position-to-angle transform optic 112. The position-to-angle transform optic 112 can be, for example, a lens. The emitted beams 151 are incident on the position-to-angle transform optic 112. Each beam emitter in the laser source 111 has a particular, fixed location with respect to the position-to-angle transform optic 112. Therefore, the emitted beams 151 have a position spectrum that corresponds to the spatial distribution of the beam emitters in the laser source 111. For example, the position of the emitted beam 151A corresponds to the position of the individual beam emitter 111A, while the position of the emitted beam 151N corresponds to the position of the individual beam emitter 111N.

Although not shown in the embodiment illustrated in FIG. 1, embodiments of the invention can include a variety of optics for manipulating beams emitted by the laser source 111 prior to their interaction with the position-to-angle transform optic 112. The optics utilized for manipulating beams emitted by the laser source 111 will vary depending on the characteristics of the laser source 111. Usually, beams emitted by diode lasers have an asymmetric beam profile, i.e. the beam diverges at disparate rates along two orthogonal axes perpendicular to its direction of propagation. The two axes can be identified as a fast axis, along which the beam diverges more rapidly, and a slow axis, upon which the beam diverges comparatively more slowly. Such manipulation of the beams may be referred to as preprocessing and can include, e.g., rotation of the beams such that downstream processing is performed along a fast axis rather than a slow axis, collimation of the beams along the fast axis, collimation of the beams along the slow axis, and the like.

The angular dispersive optic 514 is disposed downstream along the optical path from the position-to-angle transform optic 112. The position-to-angle transform optic 112 converts a position of each of the emitted beams 151 (which corresponds to a position of an beam emitter of the laser source 111) into an angle of incidence with respect to the angular dispersive optic 514. Thus, the position-to-angle transform optic 112 transforms the position spectrum of the emitted beams 151 into an angular spectrum of the emitted beams 151. The angular spectrum of the emitted beams 151 refers to the set of angles of transmission with respect to the position-to-angle transform optic 112.

The angular dispersive optic has a wavelength-dependent angular dispersion function. The angular dispersive optic 514 transforms the angular spectrum possessed by the emitted beams 151 into a wavelength-dependent angular spectrum determined by the wavelength-dependent angular dispersion function. In the embodiment depicted in FIG. 1, the angular dispersive optic 514 is a polarization insensitive optic (e.g., a polarization insensitive grating). The angular dispersive optic 514 is positioned such that a preferred resonant mode component of each constituent of the emitted beams 151 emerges from the angular dispersive optic 514 with a common direction of propagation, and as a component of the combined input beam 153. The combined input beam 153 is a combined multi-wavelength beam that includes a plurality of individual constituent beams, each of which corresponds to a constituent of the emitted beams 151.

The optical beam splitter 115 is disposed downstream along the optical path from the angular dispersive optic 514. The optical beam splitter 115 separates the combined input beam 153 by reflecting a primary portion of the combined input beam 153 as the combined output beam 158, and transmitting a secondary portion of the combined input beam 153 as the combined feedback input beam 174. The combined output beam 158 is a combined multi-wavelength laser beam that includes a plurality of individual constituent beams, each of which corresponds to a constituent of the emitted beams 151. Similarly, the combined feedback input beam 174 is a combined multi-wavelength laser beam that includes a plurality of individual constituent beams.

According to some embodiments, the optical beam splitter 115 is a polarization beam splitter, so that the polarization mode not intended to be coupled back into the diodes as optical feedback by the feedback arm 605 can be directly coupled out of the external resonator. For example, the optical beam splitter 115 can be designed such that the reflectance for the TM mode R_TM is nearly 100%. So the TM component is coupled out of the external resonator at the optical beam splitter 115, and is not transmitted into the feedback arm 605. The reflectance for the TE mode R_TE can be, for example, 85%, and transmittance for the TE mode T_TE can be 15%. So 15% of the TE component enters the feedback arm 605.

In some embodiments, the reflectance for a certain polarization (e.g., the TE mode) is greater than 80%, and the transmittance for the TE mode is less than 20%. In some embodiments, the reflectance for the TE mode is greater than 90%, and the transmittance for the TE mode is less than 10%. In some embodiments, the reflectance for the TE mode is about 92%, and the transmittance for the TE mode is about 8%, resulting in a split ratio of about 92% to 8%. Thus, the majority of the optical power of the combined input beam 153 is reflected by the optical beam splitter 115 as the combined output beam 158, and a relatively small percentage of the optical power of the combined input beam 153 is transmitted by the optical beam splitter 115 as the combined feedback input beam 174 that goes into the feedback system 605. In the case in which the reflectance of the optical beam splitter 115 for the TM mode is nearly 100%, the combined input beam 153 is nearly all in the TE mode.

The feedback system 605 is disposed downstream along the optical path from the optical beam splitter 115 to receive the combined feedback input beam 174. The feedback system 605 enables coupling the combined feedback input beam 174 into a combined feedback beam 159. The feedback system 605 includes a folding mirror 610, a spatial filtering element 611, and a first high reflectivity (HR) mirror 615. The folding mirror 610 is optional. The first HR mirror 615 reflects the combined feedback input beam 174 that has passed through the spatial filtering element 611 once back through the spatial filtering element 611 again to form the combined feedback beam 177. In some embodiments, the first HR mirror 615 has a reflectance that is greater than 98%. In some embodiments, the reflectance of the first HR mirror 615 is nearly 100%. In some embodiments, the folding mirror 610 is replaced by a combination of a polarization rotating element (e.g., a quarter-wave plate, or QWP) and a polarizer. This would allow adjustment of the optical loss of the feedback system 605 (e.g., by rotating the polarizer), enabling tuning of the effective resulting feedback into the diodes.

The spatial filtering element 611 can increase beam quality by mitigating the impact of alternative resonant mode components. The spatial filtering element 611 includes two position-to-angle transform optics 612 and 614 (e.g., two lenses) positioned about either side of an aperture 613 along the optical path between the folding mirror 610 and the first HR mirror 615. The aperture 613 filters alternative resonant mode components of each constituent of the combined feedback input beam 174 by only allowing beams with the common direction of propagation of the combined feedback input beam 174 (which is inherited from the combined input beam 153) to pass through. The two position-to-angle transform optics 612 and 614 increase the fidelity with which the aperture 613 filters out alternative resonant mode components by magnifying the angular spectrum (with respect to the common direction of propagation of the combined feedback input beam 174) possessed by the alternative resonant mode components (thereby ensuring that such components do not pass through the aperture 613). In this manner, alternative resonant mode components of the constituents of the combined feedback input beam 174 are eliminated or reduced from the combined feedback beam 177. The spatial filtering element 611 can be referred to as a beam cleaning telescope.

The combined feedback beam 177 is reflected by the folding mirror 610 toward the optical beam splitter 115. The optical beam splitter 115 transmits a secondary portion of the combined feedback beam 177 as the combined feedback beam 159. The optical power carried in the combined feedback beam 159 is ultimately provided as feedback to the plurality of beam emitters that emitted the emitted beams 151, as described below.

After emerging from the optical beam splitter 115, the combined feedback beam 159 is incident on the angular dispersive optic 514. The plurality of spatially and directionally overlapped single wavelength beams of the combined feedback beam 159 emerge from the angular dispersive optic 514 as feedback beams 160 that together possess a wavelength-dependent angular spectrum imparted by the angular dispersive optic 514. The feedback beams 160 are directed towards the laser source 111 through the position-to-angle transform optic 112. The position-to-angle transform optic 112 directs each constituent of the feedback beams 160 into an individual beam emitter of the laser source 111. The combined feedback beam 159 is thereby directed back to the plurality of beam emitters of the laser source 111 to stabilize the wavelengths of the emitted beams 151.

Specifically, the position-to-angle transform optic 112 directs each constituent of the feedback beams 160 into an individual beam emitter of the laser source 111 by converting the wavelength-dependent angular spectrum imparted on the feedback beams 160 by the angular dispersive optic 514 into a wavelength-position spectrum that corresponds to the set of preferred resonant mode wavelengths and spatial positions of each beam emitter in the laser source 111. In this manner, each constituent of the feedback beams 160 is directed into the beam emitter in the laser source 111 that emitted the corresponding constituent of the emitted beams 151. As a result, each beam emitter (or channel) in the laser source 111 adjusts the wavelength of the constituent of the emitted beams 151 that it emits to match the wavelength selected for it by the external resonator.

The optical beam splitter 115 also reflects a primary portion 185 of the combined feedback beam 177. The external cavity laser apparatus 100 also includes a second HR mirror 625 disposed in the optical path of the primary portion 185 of the combined feedback beam 177. The second HR mirror 625 reflects the primary portion 185 of the combined feedback beam 177 as a second combined feedback input beam 187, which is then reflected by the optical beam splitter 115 back toward the feedback system 605. In some embodiments, the second HR mirror 625 has a reflectance that is greater than 98%. In some embodiments, the reflectance of the second HR mirror 625 is nearly 100%. The second HR mirror 625 can recycle the optical power reflected the optical beam splitter 115.

Assuming that the spectral width of one stabilized channel is Δλ=140 pm and the wavelength λ=980 nm, the longitudinal coherence length can be estimated as

$${l}_{c} = \frac{2 ln 2}{π} \cdot \frac{{λ}^{2}}{Δ λ} = 1.31 mm$$

(assuming Gaussian spectrum). According to some embodiments, the optical path difference Δs between the first HR mirror 615 and the second HR mirror 625 can be chosen so that Δs>l_{c} (region with reasonable low interference contrast), so as to prevent beating in the output power.

As described above, the spatial filtering element 611 includes two position-to-angle transform optics 612 and 614 (e.g., two lenses) and an aperture 613. These optical components can contribute to the optical loss of the external resonator. According to embodiments of the present invention, the optical beam splitter 115 reflects the majority (e.g., about 92%) of the optical power of the combined input beam 153 as the combined output beam 158, and only a relatively low percentage (e.g., about 8%) of the optical power of the combined input beam 153 is transmitted by the optical beam splitter 115 as the combined feedback input beam 174 that goes through the feedback system 605. Thus, only the low-power combined feedback input beam 174 will experience the optical loss of the spatial filtering element 611. As a result, the optical losses of the entire apparatus can be reduced (e.g., by about 5%), as illustrated in the optical power calculations discussed below.

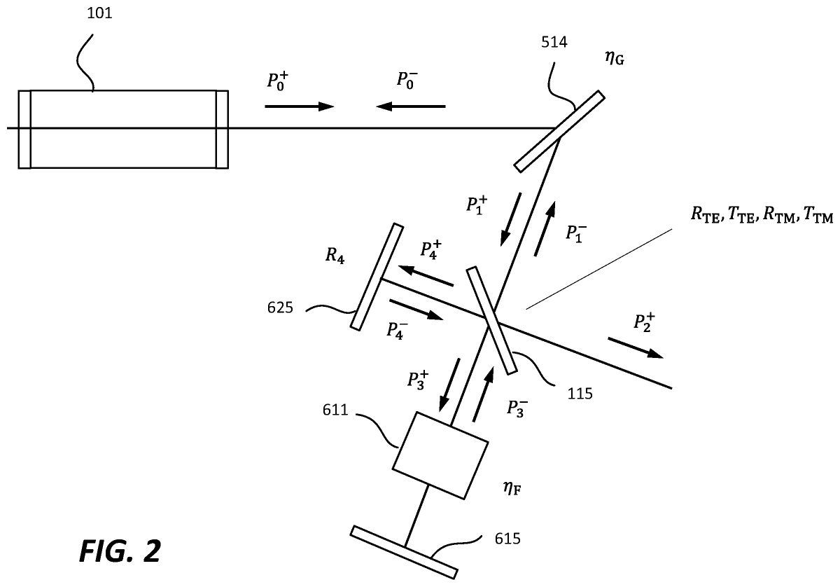

FIG. 2 is a simplified diagram of the external cavity laser apparatus 100 shown in FIG. 1, to illustrate the optical power calculations according to some embodiments. The following notations will be used in the optical power calculations. The optical power of the emitted beams emitted by the input generation system 101 is represented by P₀⁺. The optical power of the feedback beams directed back toward the input generation system 101 is represented by P₀⁻. The optical power of the beams emerging from the angular dispersive optic 514 is represented by P₁⁺. The optical power of the feedback beams incident on the angular dispersive optic 514 is represented by P₁⁻. The optical power of the combined output beam reflected or transmitted by the optical beam splitter 115 is represented by P₂⁺. The optical power of the feedback input beams transmitted by the optical beam splitter 115 is represented by P₃⁺. The optical power of the feedback beams emerging from the feedback system 605 is represented by P₃⁻. The optical power of the beams reflected by the optical beam splitter 115 toward the second HR mirror 625 is represented by P₄⁺. The optical power of the beams reflected by the second HR mirror 625 is represented by P₄⁻.

In the following, the subscript μ∈{TE, TM} is used to represent TM polarization or TE polarization, where Pᵢ^{±}=P_{i,TE}^{±}+P_{i,TM}^{±}. For example, the optical power of the emitted beams in the TM polarization state is represented by P_{0,TM}⁺, and the optical power of the emitted beams in the TE polarization state is represented by P_{0,TE}⁺, where P₀⁺=P_{0,TM}⁺P_{0,TE}⁺. Similarly, P₀⁻=P_{0,TM}⁻+P_{0,TE}⁻.

Assuming that efficiencies of the angular dispersive optic 514 is η_{G,μ}, the reflectance of the optical beam splitter 115 is R_{μ}, the transmittance of the optical beam splitter 115 is T_{μ}, the efficiency of the spatial filtering element 611 is η_{F}, and the reflectance of the second HR mirror 625 is R₄, the following equations may follow:

$${P}_{1 , μ}^{+} = {η}_{G , μ} {P}_{0 , μ}^{+} ,$$

$${P}_{2 , μ}^{+} = {R}_{μ} {P}_{1 , μ}^{+} + {T}_{μ} {P}_{4 , μ}^{-} ,$$

$${P}_{3 , μ}^{+} = {T}_{μ} {P}_{1 , μ}^{+} + {R}_{μ} {P}_{4 , μ}^{-} ,$$

$${P}_{4 , μ}^{+} = {R}_{μ} {P}_{3 , μ}^{-} ,$$

$${P}_{0 , μ}^{-} = {η}_{G , μ} {P}_{1 , μ}^{-} ,$$

$${P}_{1 , μ}^{-} = {T}_{μ} {P}_{3 , μ}^{-} ,$$

$${P}_{3 , μ}^{-} = {η}_{F} {P}_{3 , μ}^{+} , and$$

$${P}_{4 , μ}^{-} = {R}_{4} {P}_{4 , μ}^{+} .$$

Substituting some of the equations, the following can be obtained:

$${P}_{1 , μ}^{+} = {η}_{G , μ} {P}_{0 , μ}^{+} ,$$

$${P}_{2 , μ}^{+} = ( {R}_{μ} {η}_{G , μ} + \frac{{R}_{4} {R}_{μ} {η}_{F , μ} {η}_{G , μ} {T}_{μ}^{2}}{1 - {R}_{μ}^{2} {R}_{4} {η}_{F , μ}} ) {P}_{0 , μ}^{+} ,$$

$${P}_{3 , μ}^{+} = \frac{{η}_{G , μ} {T}_{μ}}{1 - {R}_{μ}^{2} {R}_{4} {η}_{F , μ}} {P}_{0 , μ}^{+} ,$$

$${P}_{4 , μ}^{+} = \frac{{η}_{F , μ} {η}_{G , μ} {T}_{μ} {R}_{μ}}{1 - {R}_{μ}^{2} {R}_{4} {η}_{F , μ}} {P}_{0 , μ}^{+} ,$$

$${P}_{0 , μ}^{-} = \frac{{η}_{F , μ} {η}_{G , μ}^{2} {T}_{μ}^{2}}{1 - {R}_{μ}^{2} {R}_{4} {η}_{F , μ}} {P}_{0 , μ}^{+} ,$$

$${P}_{1 , μ}^{-} = \frac{{η}_{F , μ} {η}_{G , μ} {T}_{μ}^{2}}{1 - {R}_{μ}^{2} {R}_{4} {η}_{F , μ}} {P}_{0 , μ}^{+} ,$$

$${P}_{3 , μ}^{-} = \frac{{η}_{F , μ} {η}_{G , μ} {T}_{μ}}{1 - {R}_{μ}^{2} {R}_{4} {η}_{F , μ}} {P}_{0 , μ}^{+} , and$$

$${P}_{4 , μ}^{-} = \frac{{R}_{4} {η}_{F , μ} {η}_{G , μ} {T}_{μ} {R}_{μ}}{1 - {R}_{μ}^{2} {R}_{4} {η}_{F , μ}} {P}_{0 , μ}^{+} .$$

The effective external reflectivity is defined as the ratio of the optical power of the feedback beams 160 to the optical power of the emitted beams 151:

$${R}_{ext} = \frac{{P}_{0}^{-}}{{P}_{0}^{+}} ,$$

The efficiency of the external cavity laser apparatus 100 is defined as the ratio of the sum of the optical power of the combined output beam 158 and the optical power of the feedback beams 160 to the optical power of the emitted beams 151:

$${η}_{ext} = \frac{{P}_{2}^{+} + {P}_{0}^{-}}{{P}_{0}^{+}} .$$

The output efficiency of the external cavity laser apparatus 100 is defined as the ratio of optical power of the combined output beam 158 to the optical power of the emitted beams 151:

$${η}_{out} = \frac{{P}_{2}^{+}}{{P}_{0}^{+}} .$$

The following equations can be obtained:

$${R}_{ext} = \frac{{P}_{0}^{-}}{{P}_{0}^{+}} = \frac{{η}_{F , μ} {η}_{G , μ}^{2} {T}_{μ}^{2}}{1 - {R}_{μ}^{2} {R}_{4} {η}_{F , μ}} ,$$

$${η}_{ext} = \frac{{P}_{2}^{+} + {P}_{0}^{-}}{{P}_{0}^{+}} = {R}_{μ} {η}_{G , μ} + \frac{{R}_{4} {R}_{μ} {η}_{F , μ} {η}_{G , μ} {T}_{μ}^{2}}{1 - {R}_{μ}^{2} {R}_{4} {η}_{F , μ}} + \frac{{η}_{F , μ} {η}_{G , μ}^{2} {T}_{μ}^{2}}{1 - {R}_{μ}^{2} {R}_{4} {η}_{F , μ}} , and$$

$${η}_{out} = \frac{{P}_{2}^{+}}{{P}_{0}^{+}} = {R}_{μ} {η}_{G , μ} + \frac{{R}_{4} {R}_{μ} {η}_{F , μ} {η}_{G , μ} {T}_{μ}^{2}}{1 - {R}_{μ}^{2} {R}_{4} {η}_{F , μ}} .$$

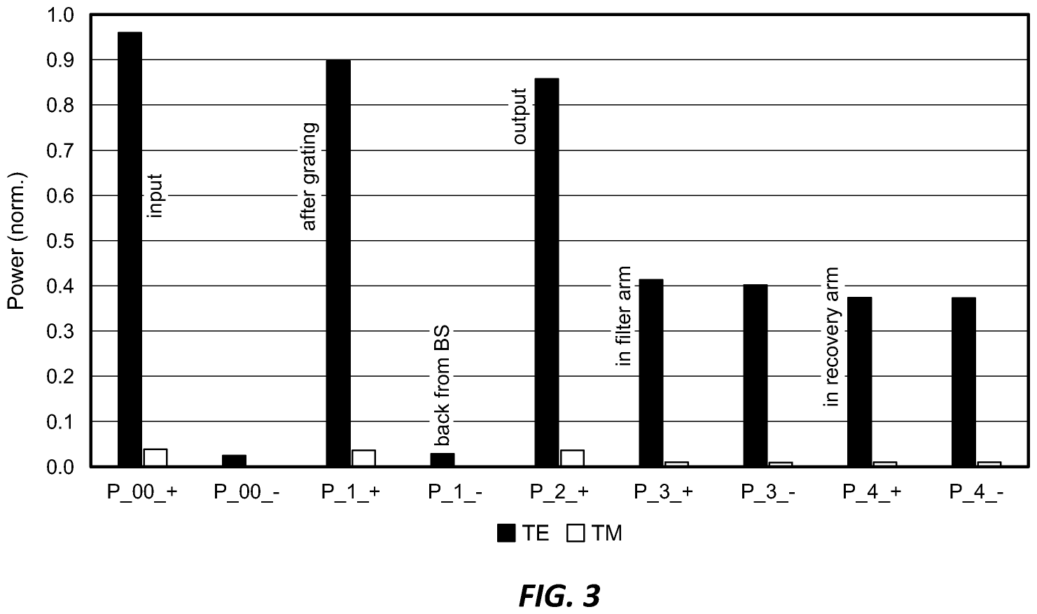

FIG. 3 shows a bar plot of the optical powers of P_{0,μ}⁺, P_{0,μ}⁻, P_{1,μ}⁺, P_{1,μ}⁻, P_{2,μ}⁺, P_{3,μ}⁺, P_{3,μ}⁻, P_{4,μ}⁺, P_{4,μ}⁻, where μ∈{TE, TEM}, according to some embodiments. Table 1 shows the calculated values of the effective external reflectivity Rₑₓₜ, the efficiency of the external system ηₑₓₜ, and the output efficiency ηₒᵤₜ, and the assume values of the efficiency of the spatial filtering element 611 η_{F}, the efficiency of the angular dispersive optic 514 η_{G} (assuming that the angular dispersive optic 514 is polarization insensitive), the reflectances of the optical beam splitter 115 R_{TE} and R_{TM}, and the transmittances of the optical beam splitter 115 T_{TE} and T_{TM}, (the value of the reflectance of the second HR mirror 625 R₄ is assumed to be 1.0), according to some embodiments.

TABLE 1

| Rₑₓₜ | ηₑₓₜ | ηₒᵤₜ | η_{F} | η_{G} | R_{TE} | T_{TE} | R_{TM} | T_{TM} |
|---|---|---|---|---|---|---|---|---|
| 0.029 | 0.923 | 0.895 | 0.979 | 0.935 | 0.925 | 0.075 | 0.982 | 0.018 |

As illustrated in Table 1, the effective external reflectivity Rₑₓₜ is about 3%. Thus, only about 3% of the optical power of emitted beams 151 is in the feedback beams 160 to stabilize the wavelengths of the emitted beams 151. The output efficiency ηₒᵤₜ can be as high as 89%. In comparison, conventional systems that include the spatial filtering element in the high-power branch, the output efficiency ηₒᵤₜ is only about 81%, Thus, a reduction of optical loss of approximately 8% compared to conventional systems can be realized according to embodiments of the present invention. Similarly, the efficiency of the external cavity laser apparatus 100 ηₑₓₜ can be as high as 92%, as compared to 85% achievable in conventional systems.

According to embodiments of the present invention, the external resonator is polarization insensitive, and can be designed for either TM or TE mode (relative to the laser emitters). Thus polarization multiplexing of boards in a large laser system is also possible. According to some embodiments, the optical beam splitter 115 can be designed such that it reflects nearly all TM mode to the combined output beam 158, and therefore reducing the needed feedback compared to conventional systems. Back reflected TM radiation does not contribute to the feedback.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

What is claimed is:

1. An external cavity laser apparatus comprising:
a plurality of beam emitters configured to emit a plurality of emitted beams, each emitted beam having a respective wavelength;
an angular dispersive optic disposed in an optical path of the plurality of emitted beams and configured to combine the plurality of emitted beams into a combined input beam;
an optical beam splitter disposed in an optical path of the combined input beam and having a first reflectance for a first polarization state and a first transmittance for the first polarization state, the first transmittance being unequal to the first reflectance, the optical beam splitter configured to:
reflect a primary portion of the combined input beam as a combined output beam; and
transmit a secondary portion of the combined input beam as a combined feedback input beam;
a spatial filtering element disposed in an optical path of the combined feedback input beam; and
a first high reflectance (HR) mirror disposed in the optical path of the combined feedback input beam downstream from the spatial filtering element, the first HR mirror configured to reflect the combined feedback input beam transmitted through the spatial filtering element once back through the spatial filtering element again to form a combined feedback beam;
wherein a primary portion of the combined feedback beam is reflected by the optical beam splitter, and a secondary portion of the combined feedback beam is transmitted by the optical beam splitter toward the angular dispersive optic; and
wherein the secondary portion of the combined feedback beam is directed by the angular dispersive optic back to the plurality of beam emitters to stabilize the wavelengths of the plurality of emitted beams.

2. The external cavity laser apparatus of claim 1, further comprising a second HR mirror disposed in an optical path of the primary portion of the combined feedback beam reflected by the optical beam splitter, the second HR mirror configured to reflect the primary portion of the combined feedback beam back toward the optical beam splitter.

3. The external cavity laser apparatus of claim 2, wherein the second HR mirror has a reflectance that is greater than 98%.

4. The external cavity laser apparatus of claim 1, wherein the first reflectance is greater than the first transmittance.

5. The external cavity laser apparatus of claim 4, wherein the optical beam splitter has a second reflectance for a second polarization state orthogonal to the first polarization state, the second reflectance being greater than 98%.

6. The external cavity laser apparatus of claim 4, wherein the first reflectance is greater than 80%, and the first transmittance is less than 20%.

7. The external cavity laser apparatus of claim 6, wherein the first reflectance is greater than 90%, and the first transmittance is less than 10%.

8. The external cavity laser apparatus of claim 1, wherein the first HR mirror has a reflectance that is greater than 98%.

9. The external cavity laser apparatus of claim 1, wherein the angular dispersive optic is a polarization insensitive grating.

10. The external cavity laser apparatus of claim 1, further comprising a first position-to-angle transform optic disposed in the optical path of the plurality of emitted beams upstream from the angular dispersive optic, the first position-to-angle transform optic configured to impart upon each of the plurality of emitted beams an angle of incidence with respect to the angular dispersive optic.

11. The external cavity laser apparatus of claim 10, wherein the angular dispersive optic has a wavelength-dependent angular dispersion function, so that the angular dispersive optic combines the plurality of emitted beams into the combined input beam by imparting a wavelength-dependent angular spectrum determined by the wavelength-dependent angular dispersion function on the plurality of emitted beams.

12. The external cavity laser apparatus of claim 11, wherein the spatial filtering element comprises:
a second position-to-angle transform optic;
a third position-to-angle transform optic; and
an aperture disposed between the second position-to-angle transform optic and the third position-to-angle transform optic.

13. The external cavity laser apparatus of claim 1, further comprising a polarizer and a polarization rotating element disposed between the optical beam splitter and the spatial filtering element in the optical path of the combined feedback input beam.

14. A method of dense wave multiplexing comprising:
generating, using a plurality of beam emitters, a plurality of emitted beams, each emitted beam having a respective wavelength;
combining, using an angular dispersive optic disposed in an optical path of the plurality of emitted beams, the plurality of emitted beams into a combined input beam;
splitting, using an optical beam splitter, the combined input beam into a primary portion and a secondary portion, an optical power of the primary portion being different than an optical power of the secondary portion, the primary portion being reflected by the optical beam splitter as a combined output beam, and the secondary portion being transmitted by the optical beam splitter as a combined feedback input beam;
passing the combined feedback input beam through a spatial filtering element to form a combined feedback beam directed toward the optical beam splitter;
transmitting, using the optical beam splitter, a secondary portion of the combined feedback beam toward the angular dispersive optic; and
directing, using the angular dispersive optic, the secondary portion of the combined feedback beam back to the plurality of beam emitters to stabilize the wavelengths of the plurality of emitted beams.

15. The method of claim 14, wherein the optical power of the primary portion of the combined input beam is greater than the optical power of the secondary portion of the combined input beam.

16. The method of claim 15, wherein the optical power of the primary portion of the combined input beam is greater than 80% of an optical power of the combined input beam, and the optical power of the secondary portion of the combined input beam is less than 20% of the optical power of the combined input beam.

17. The method of claim 16, wherein the optical power of the primary portion of the combined input beam is greater than 90% of the optical power of the combined input beam, and the optical power of the secondary portion of the combined input beam is less than 10% of the optical power of the combined input beam.

18. The method of claim 14, further comprising:
reflecting, using the optical beam splitter, a primary portion of the combined feedback beam; and
reflecting, using a high reflectance (HR) mirror, the primary portion of the combined feedback beam back toward the optical beam splitter.

19. The method of claim 14, wherein the spatial filtering element comprises:
a first position-to-angle transform optic;
a second position-to-angle transform optic; and
an aperture disposed between the second position-to-angle transform optic and the third position-to-angle transform optic.

20. The method of claim 19, wherein passing the combined feedback input beam through the spatial filtering element comprises passing the combined feedback input beam through the spatial filtering element for a first time and a second time, and the method further comprising:
after passing the combined feedback input beam through the spatial filtering element for the first time, reflecting, using a high reflectance (HR) mirror, the combined feedback input beam back through the spatial filtering element for the second time.
